(19) United States
(12) Patent Application Publication
(10) Pub. No.: US 2019/0049599 A1
(43) Pub. Date: Feb. 14, 2019

(54) IMAGING APPARATUS, IMAGING DISPLAY SYSTEM, AND DISPLAY APPARATUS

(71) Applicant: SONY CORPORATION, Tokyo (JP)

(72) Inventors: Katsuji MATSUMOTO, Kanagawa (JP); Shusaku YANAGAWA, Kanagawa (JP); Takahiro IGARASHI, Kanagawa (JP); Hiroshi ICHIKI, Kanagawa (JP)

(73) Assignee: SONY CORPORATION, Tokyo (JP)

(21) Appl. No.: 16/077,965

(22) PCT Filed: Jan. 17, 2017
(86) PCT No.: PCT/JP2017/001378

§ 371 Date: Aug. 14, 2018

(30) Foreign Application Priority Data
Feb. 22, 2016 (JP) 2016-031110

(51) Int. Cl. G01T 1/20; H01L 27/146; H01L 23/538

(52) U.S. Cl. CPC G01T 1/2018; H01L 27/14609; H01L 23/5387; H01L 24/16; H01L 27/14636; H01L 27/14618; H01L 27/14663

(57) ABSTRACT

An imaging apparatus includes: a substrate; and a plurality of device sections each including a photoelectric converter and disposed on the substrate to be spaced from one another and to collectively form a concave shape.

### TECHNICAL FIELD

The present disclosure relates to an imaging apparatus, an imaging display system, and a display apparatus that detect a radioactive ray such as an α-ray, a β-ray, a γ-ray, or an x-ray.

### BACKGROUND ART

Many imaging apparatuses applied to large FPDs (flat panel detectors) that image, for example, a chest, etc. employ amorphous silicon. With this imaging apparatus, which images an object while retaining a predetermined distance from a radiation source, sensitivity lowers in a periphery of an image to cause image degradation because the imaging apparatus is located away from the radiation source.

Thus, for example, PTL 1 proposes a technique of suppressing resolution reduction as described above using a fiber optic plate having a processed surface shape.

### CITATION LIST

### Patent Literature

PTL 1: Japanese Unexamined Patent Application Publication No. H09-112301

### SUMMARY OF THE INVENTION

However, with the technique disclosed in the above-described PTL 1, light is easily trapped in the fiber optic plate. This reduces photosensitivity, which leads to image degradation. It is desirable to achieve a technique of suppressing the image degradation without using such an optical member.

It is therefore desirable to provide an imaging apparatus, an imaging display system, and a display apparatus that make it possible to suppress the image degradation.

An imaging apparatus according to an embodiment of the present disclosure includes: a substrate; and a plurality of device sections each including a photoelectric converter and disposed on the substrate to be spaced from one another and to collectively form a concave shape.

An imaging display system according to an embodiment of the present disclosure includes the above-described imaging apparatus according to the present disclosure.

In the imaging apparatus and the imaging display system according to the embodiments of the present disclosure, the plurality of device sections each including the photoelectric converter are disposed to collectively form the concave shape. This suppresses sensitivity degradation in a periphery, as compared with device sections being disposed in a flat shape. Moreover, disposing the plurality of device sections spaced from one another on the substrate makes it easier to retain the concave shape and reduces occurrence of distortion due to bending stress, as compared with device sections being successively disposed with no space between them on the substrate.

A display apparatus according to an embodiment of the present disclosure includes: a substrate; and a plurality of device sections each including a light emitting device and disposed on the substrate to be spaced from one another and to collectively form a concave shape.

In the display apparatus according to the embodiment of the present disclosure, a plurality of device sections each including the light emitting device are disposed to collectively form the concave shape and to be spaced from one another. This makes it easier to retain the concave shape and reduces occurrence of distortion due to bending stress, as compared with device sections being successively disposed with no space between them on the substrate.

In the imaging apparatus and the imaging display system according to the embodiments of the present disclosure, the plurality of device sections each including the photoelectric converter are disposed to collectively form the concave shape. This suppresses sensitivity degradation in the periphery, as compared to device sections being disposed in a flat shape. Moreover, disposing the plurality of device sections spaced from one another on the substrate makes it easier to retain the concave shape and reduces occurrence of distortion due to bending stress. This makes it possible to suppress functional degradation of the device sections due to the distortion. Thus, it is possible to suppress degradation in image quality of an obtained image.

In the display apparatus according to the embodiment of the present disclosure, the plurality of device sections each including the light emitting device collectively form the concave shape and are disposed to be spaced from one another. This makes it easier to retain the concave shape and reduces occurrence of distortion due to bending stress. This suppresses the functional degradation of the device sections caused by the distortion. Thus, it is possible to suppress degradation in image quality of a displayed image.

It is to be noted that the contents described above are merely examples of the present disclosure. Effects of the present disclosure are not limited to the effects described above, and may be or may further include any other effect.

### BRIEF DESCRIPTION OF DRAWINGS

FIG. 1 is a cross-sectional view of a schematic configuration of an imaging apparatus according to an embodiment of the present disclosure.

FIG. 2 is an enlarged cross-sectional view of a configuration of a part of the imaging apparatus illustrated in FIG. 1.

FIG. 3 is a schematic view for description of a planar configuration of a pixel array section of the imaging apparatus illustrated in FIG. 1.

FIG. 4 is a diagram illustrating a circuit configuration of a device section of the imaging apparatus illustrated in FIG. 1.

FIG. 5 is a schematic cross-sectional view for description of a concave shape of the imaging apparatus illustrated in FIG. 1.

FIG. 6A is a schematic cross-sectional view for description of another example of the concave shape.

FIG. 6B is a schematic cross-sectional view for description of another example of the concave shape.

FIG. 7A is a cross-sectional view for description of a process of a method of manufacturing the imaging apparatus illustrated in FIG. 1.

FIG. 7B is a cross-sectional view of a process following FIG. 7A.

FIG. 7C is a cross-sectional view of a process following FIG. 7B.

FIG. 8 is a cross-sectional view of a process following FIG. 7C.

FIG. 9 is a cross-sectional view of a process following FIG. 8.

FIG. 10 is a schematic view of a configuration of an imaging apparatus according to a comparative example 1.

FIG. 11 is a schematic view of a configuration of an imaging apparatus according to a comparative example 2.

FIG. 12 is a chart illustrating relations among a distance from a source, a degree of curvature of the concave shape, and peripheral sensitivity of the imaging apparatus illustrated in FIG. 1.

FIG. 13 is a functional block diagram illustrating an overall configuration of the imaging apparatus according to a modification example 1.

FIG. 14 is a diagram illustrating a circuit configuration of the pixel array section illustrated in FIG. 13.

FIG. 15 is a diagram illustrating an example of a schematic configuration of an imaging display system according to an application example.

FIG. 16 is a cross-sectional view of a configuration of a display apparatus according to a modification example 2.

### BEST MODES FOR CARRYING OUT THE INVENTION

In the following, some embodiments of the present disclosure are described in detail with reference to the drawings. It is to be noted that description is made in the following order.
1. Embodiment (An example of an imaging apparatus in which a plurality of device sections including a photoelectric converter and an IV converter circuit are disposed to be spaced from one another and to form a concave shape)
2. Modification Example 1 (An example of a case having a passive pixel circuit)
3. Application Example (An example of an imaging display system)
4. Modification Example 2 (An example of a display apparatus)

### Embodiment

### [Configuration]

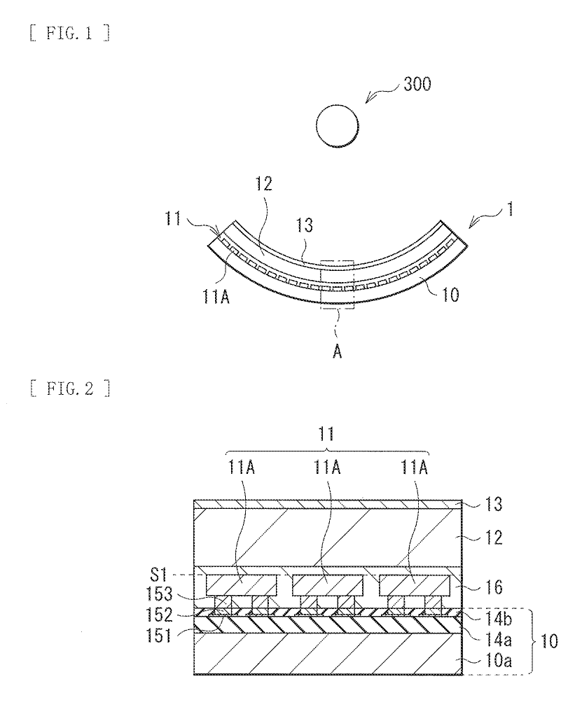

FIG. 1 illustrates an example of a cross-sectional configuration of an imaging apparatus (imaging apparatus 1) according to an embodiment of the present disclosure together with a radiation source (source 300). FIG. 2 is an enlargement of a region A that is a part of FIG. 1. The imaging apparatus 1 is a radiation detector that detects a radioactive ray such as an α-ray, β-ray, γ-ray, or an x-ray, and is, for example, an imaging apparatus of an indirect conversion system. The indirect conversion system means a system of converting a radioactive ray into an optical signal and then into an electric signal. The imaging apparatus 1 includes, for example, a pixel array section 11, a wavelength conversion layer 12, and a reflection layer 13 in this order on a wiring substrate 10.

The wiring substrate 10 includes, for example, a plurality of wiring layers (wiring layers 151) on a substrate 10a. The substrate 10a includes, for example, glass, silicon (Si), or an organic resin. The wiring substrate 10 including the substrate 10a has a curved shape that includes a concave face on a side where a device section 11A is provided (a side facing the source 300). The substrate 10a includes a bendable material with a bendable thickness (e.g. the substrate 10a is bent after being thinned in a manufacturing process). On a region facing the device section 11A of the wiring substrate 10, for example, a switching device is not provided, but only the wiring layer 151 for transmission of an electric signal to the device section 11A to be described later is provided.

The pixel array section 11 includes a plurality of device sections 11A disposed in two dimensions. Each device section 11A configures a single pixel in the imaging apparatus 1.

The plurality of device sections 11A include respective photoelectric converters and are disposed to be spaced from one another (have a gap between the device sections 11A). Each of the plurality of device sections 11A is soldered on the wiring substrate 10. The photoelectric converter is, for example, a photodiode. The photoelectric converter has a function of converting incident light into a current signal, and has a light receiving surface on a side on which the wavelength conversion layer 12 is located.

For example, the wiring layer 151 formed on the wiring substrate 10 and the device section 11A are electrically coupled to each other. The wiring layer 151 is formed on an insulating film 14a and embedded in an insulating film 14b. A UBM (Under Bump Metal) penetrating the insulating film 14b is formed on the wiring layer 151, and the device section 11A is disposed on the UBM 152 with a solder layer 153 in between. A buried layer 16 is formed to fill the gap between the device sections 11A.

The insulating films 14a and 14b each include an inorganic insulating film such as silicon oxide (SiO₂) and silicon nitride (SiN) or an organic resin that is formable by coating. The wiring layer 151 may include an elemental substance such as aluminum (Al) or copper (Cu) or may include an alloy of aluminum or copper. Exemplary aluminum alloys include alloys containing, for example, Cu, Si, and SiCu. The UBM 152 is a laminated film containing, for example, nickel (Ni), platinum (Pt), and gold (Au), and functions as a solder diffusion suppressing layer. The solder layer 153 includes an alloy containing, for example, lead or tin as a major component, and is formed by, for example, electrolytic plating, imprinting of solder paste, etc. The buried layer 16 includes, for example, an inorganic insulating film such as silicon oxide and silicon nitride, or an organic resin.

The wavelength conversion layer 12 converts the incident radioactive ray into a ray having a wavelength in a sensitivity range of the photoelectric converter of the device section 11A, and specifically includes a phosphor (scintillator) that converts the radioactive ray such as the α-ray, the β-ray, the γ-ray, or the x-ray into visible light. Examples of such a phosphor include cesium iodide (CsI) doped with thallium (Tl) or sodium (Na) and sodium iodide (NaI) doped with thallium (Tl). Moreover, examples of the phosphor include cesium bromide (CsBr) doped with europium (Eu) and cesium fluorobromide (CsBrF) doped with europium (Eu). The wavelength conversion layer 12 includes a columnar scintillator or a granular scintillator, for example, and has a concave shape corresponding to the concave shape of the pixel array section 11.

The reflection layer 13 has a role of returning light outputted from the wavelength conversion layer 12 in a direction opposite to the device section 11A toward the device section 11A. The reflection layer 13 may include a moisture impermeable material that is substantially impermeable to moisture. In such a case, permeation of moisture to the wavelength conversion layer 12 is preventable by the reflection layer 13. The reflection layer 13 may include a plate-like member such as sheet glass, and may include a vapor-deposited film of aluminum, for example. The reflection layer 13 may be omitted.

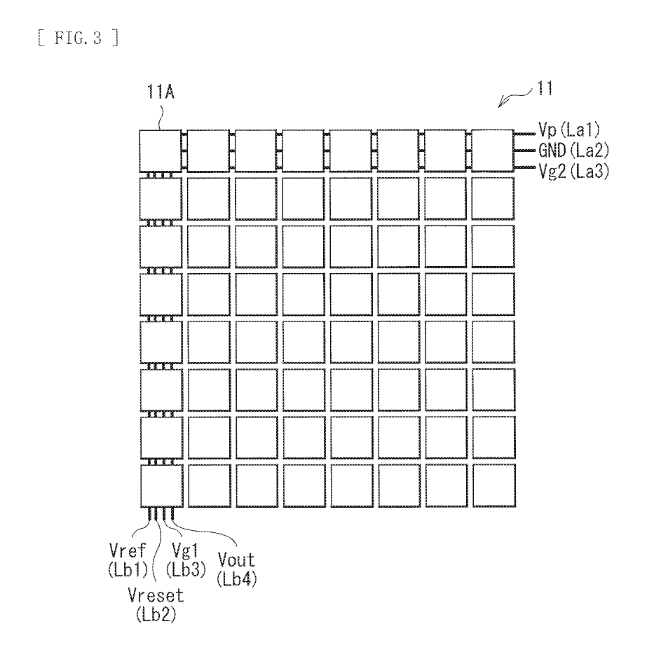

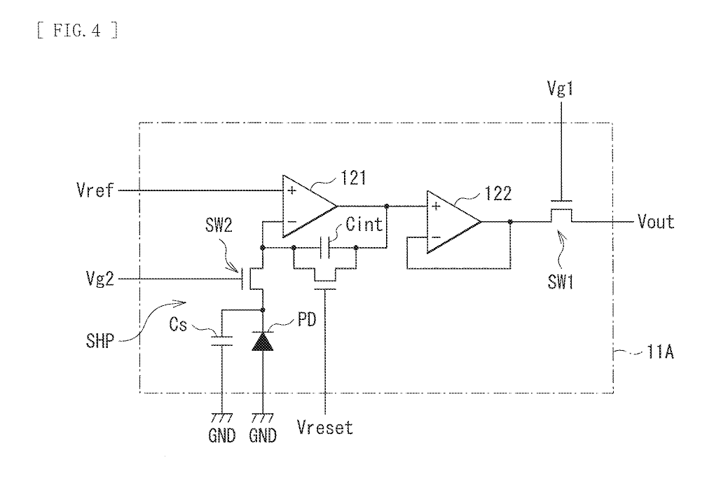

FIG. 3 is a schematic view for description of a planar configuration of the pixel array section 11 including the device sections 11A as described above. FIG. 4 illustrates a circuit configuration of each device section 11A. In this embodiment, the device section 11A includes a so-called active pixel circuit that includes, along with the photoelectric converter (photodiode PD), an IV converter circuit (current-voltage converter circuit) that converts an optical signal to an electric signal.

In the pixel array section 11, as illustrated in FIG. 3, a plurality of device sections 11A are disposed in a two-dimensional array and spaced from one another. In the pixel array section 11, a plurality of lines are disposed in each row (pixel row) or each column (pixel column). For example, lines La1, La2, La3 that respectively supply a source voltage Vp, a ground voltage GND, and an SHP (sample and hold) switch control voltage Vg2 to each device section 11A are formed in each row. Moreover, there are provided lines Lb1, Lb2, Lb3 that respectively supply a reference voltage Vref, a reset voltage Vreset, and an address switch control voltage Vg1 to each device section 11A, and a line Lb4 that reads a signal voltage Vout from each device section 11A are formed in each column.

As illustrated in FIG. 4, the device section 11A includes, for example, the photodiode PD, an address switch SW1, a switch SW2 that configures an SHP circuit, and comparators 121 and 122. Voltages to drive each device section 11A are supplied through the above-described various lines La1, La2, La3, Lb1, Lb2, Lb3, and a signal voltage is read through the line Lb4. The lines La1 to La3 and Lb1 to Lb4 are formed as the wiring layer 151 on the wiring substrate 10.

In this embodiment, a plurality of device sections 11A (pixel array sections 11) as described above collectively have a concave shape (are disposed in a concave shape). Particularly, while a face S1 on a light receiving side of the pixel array section 11 has the concave shape, the concave shape of each device section 11A is gentler than that of the pixel array section 11 (the concave shape formed by all the plurality of device sections 11A). That is, the concave shape of each device section 11A is made gentler than the curved shape of the wiring substrate 10 (substrate 10a). Moreover, the entire imaging apparatus 1 including the wiring substrate 10 (substrate 10a), the pixel array section 11, the wavelength conversion layer 12, and the reflection layer 13 is retained in a curved state. The concave shape of the pixel array section 11 is formed along the curved shape of the wiring substrate 10.

A degree of curvature of the concave shape of the pixel array section 11 is desirably, for example, 6 degrees or more. Although the details will be described later, this is because sufficient sensitivity is ensured in a periphery, for example, upon imaging in a recumbent position. Here, the degree of curvature corresponds to an angle (angle D) between a segment connecting a center p1 of the face S1 on the light receiving side of the pixel array section 11 to a periphery p2 thereof and a ground contact face S2, as illustrated in FIG. 5. The pixel array section 11 desirably has a shape gently curving from the center toward the periphery as illustrated in FIGS. 1 and 5. More desirably, the concave shape of the pixel array section 11 has a curvature (the concave shape forms an arc). The device sections 11A are disposed at an equal distance from the source 300, which makes it possible to achieve a uniform resolution all over the pixel array section 11.

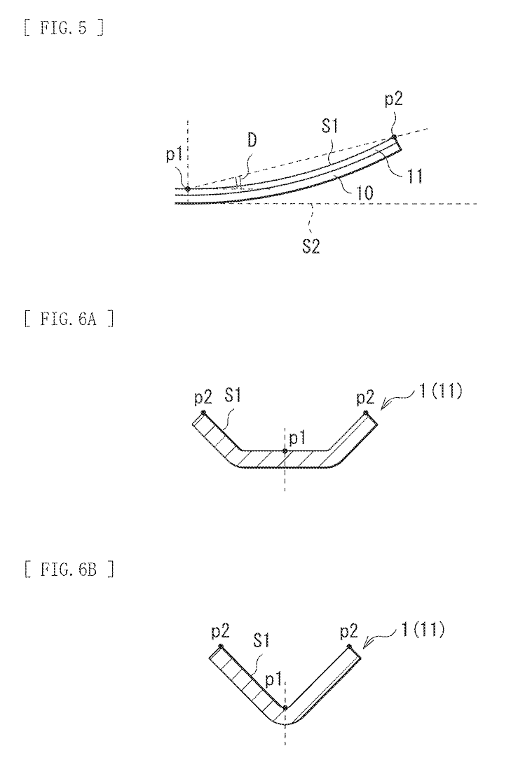

However, the concave shape of the pixel array section 11 is not limited to the gently curved shape as described above. The pixel array section 11 has only to collectively form a concave shape, and the concave shape may have, for example, a bending portion on a side on which the periphery p2 is located, as illustrated in FIG. 6A. Moreover, the concave shape may have a bending portion at the center p1, as illustrated in FIG. 6B.

### [Manufacturing Method]

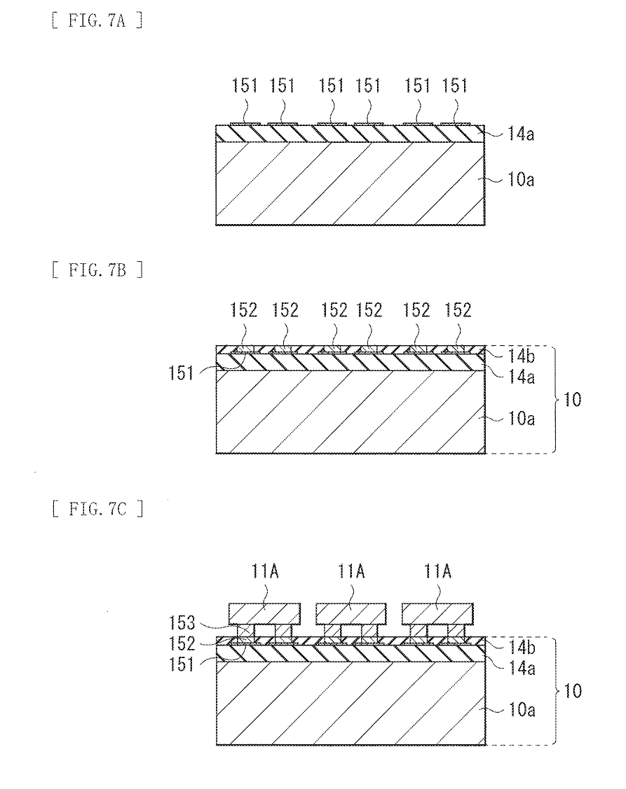

The imaging apparatus 1 as described above is manufacturable as follows, for example. FIGS. 7A to 9 illustrate the steps of manufacturing the imaging apparatus 1 in process order.

First, the wiring substrate 10 is fabricated. Specifically, as illustrated in FIG. 7A, the insulating film 14a including the above-described material is formed on the substrate 10a by a CVD method or the like, and thereafter, the wiring layer 151 is formed thereon. The wiring layer 151 is formed in the following manner, for example. That is, a film is formed with the above-described material by, for example, a sputtering method or the like, and thereafter, the film is processed by etching (dry etching or wet etching) using a photolithography method to form the wiring layer 151. Alternatively, a seed metal layer and a photoresist film are formed by a sputtering method, and thereafter, a portion where wiring is not necessary of the resist film is patterned. Then, electrolytic plating is performed to form a conductive layer in a predetermined portion, and thereafter, the resist film is removed. After that, the conductive film is etched to remove an unnecessary seed metal layer and an unnecessary plating film. The wiring layer 151 is formable in this manner.

Subsequently, as illustrated in FIG. 7B, the insulating film 14b including the above-described material is formed by a CVD method, for example, and thereafter, the UBM 152 is formed. Specifically, an opening is formed in the insulating film 14b, and thereafter, the UBM 152 including the above-described material is formed in the opening, for example, by electrolytic plating or electroless plating. The wiring substrate 10 is formable in this manner.

Next, as illustrated in FIG. 7C, the plurality of device sections 11A are soldered on the wiring substrate 10. Specifically, the device sections 11A are overlaid on the UBM 152 with the solder layer 153 in between, and thereafter, the solder layer 153 is pressure-bonded by reflow soldering to adhere each device section 11A to the wiring substrate 10. This allows for mounting of the plurality of device sections 11A as being spaced from one another on the wiring substrate 10.

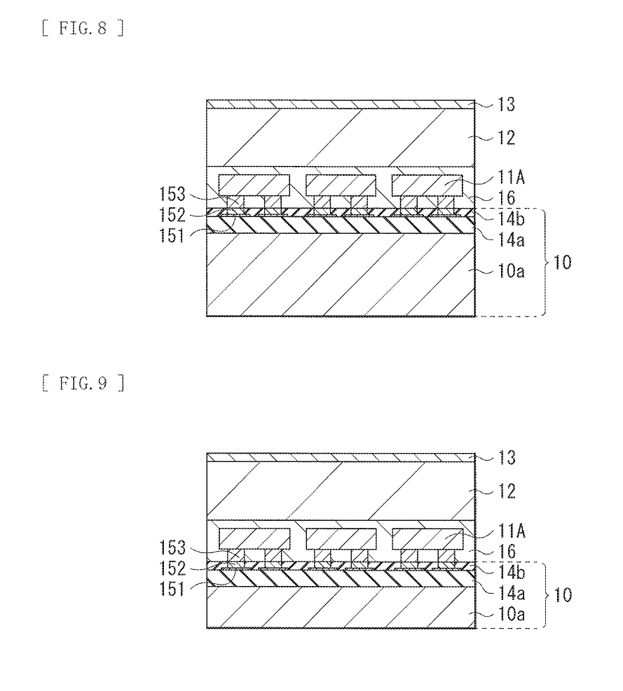

Subsequently, as illustrated in FIG. 8, the buried layer 16 including the above-described material is formed on the plurality of device sections 11A to fill the gap between the device sections 11A. Thereafter, crystal growth is performed by a vacuum deposition method to form the wavelength conversion layer 12 including the above-described material. The reflection layer 13 is then formed on the wavelength conversion layer 12.

Next, as illustrated in FIG. 9, in a case where the substrate 10a is a hard substrate such as glass and quartz, the substrate 10a is thinned by using a chemical solution or by abrading a portion of the substrate 10a by physical polishing. Specifically, thinning is performed until the substrate 10a has a physically bendable thickness. Alternatively, in a case where the substrate 10a includes an organic resin, the substrate 10a may be delaminated (removed) by, for example, laser irradiation on a back side.

It is to be noted that the substrate 10a may be thinned after the process illustrated in FIG. 7C (the process of mounting the device sections 11A). Moreover, after thinning or delaminating the substrate 10a, the wiring substrate 10 and the pixel array section 11 are bent to form the concave shape as described above on the light receiving surface side of the pixel array section 11. The bending process may be performed at any timing after thinning or delaminating the substrate 10a. In this manner, the imaging apparatus 1 illustrated in FIGS. 1 and 2 is completed.

### [Workings and Effects]

In the above-described imaging apparatus 1, the radioactive ray emitted from the source 300 enters the wavelength conversion layer 12, and thereafter, the wavelength conversion layer 12 outputs light (e.g. visible light). Thereafter, the light enters each device section 11A and then is converted into an electric signal by the photoelectric converter (photodiode PD). The electric signal is read out with from each device section 11A, transmitted to the wiring substrate 10, and then outputted to an external circuit. This makes it possible to detect the radioactive ray as the electric signal.

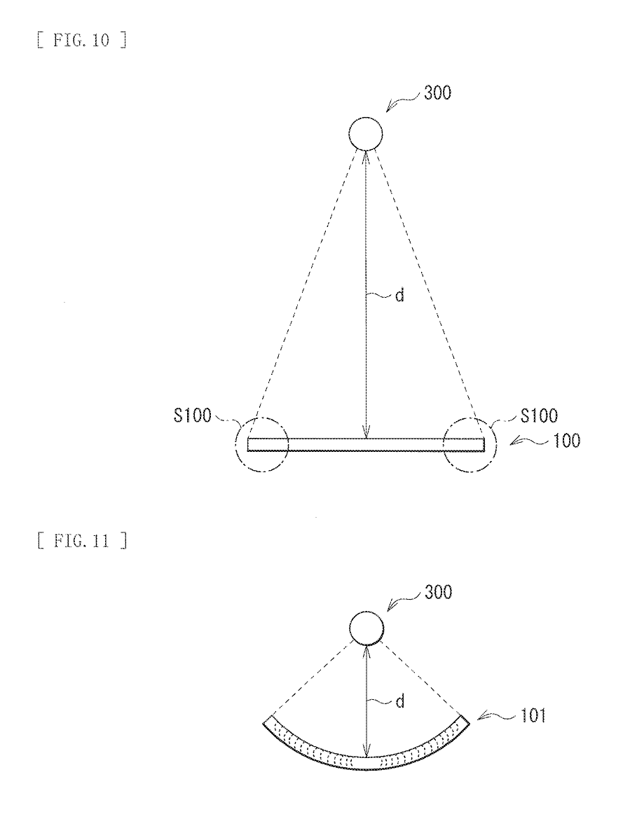

Now, FIG. 10 illustrates a configuration of an imaging apparatus 100 according to a comparative example (comparative example 1) of the embodiment together with the source 300. The imaging apparatus 100 according to the comparative example 1 is, for example, a large FPD for chest, etc., and includes amorphous silicon. The imaging apparatus 100 has a flat shape as a whole. The source 300 is disposed at a distance d from a light receiving surface of the imaging apparatus 100. Shooting is performed in a state in which an object is placed between the source 300 and the imaging apparatus 100.

However, to ensure the predetermined distance d, in such an imaging apparatus 100, sensitivity degradation and distortion occurs more easily in a periphery S₁₀₀ than a center.

It is therefore desirable to curve the entire apparatus like an imaging apparatus 101 of a comparative example 2 illustrated in FIG. 11. Thus, in the imaging apparatus 101 having a curved shape, it is possible to make the distance d between the source 300 and the imaging apparatus 101 equal both at the center and in the periphery, thereby suppressing sensitivity degradation in the periphery. In the imaging apparatus 101, however, the photoelectric converters are successively disposed on the substrate with no space therebetween, which causes distortion by bending to degrade the device section, specifically a circuit section including the switching device.

In contrast, in this embodiment, the plurality of device sections 11A including the photoelectric converters are disposed on the wiring substrate 10 to collectively form a concave shape. This suppresses sensitivity degradation in the periphery, as compared with device sections being disposed in a flat shape (comparative example 1). Moreover, disposing the plurality of device sections 11A spaced from one another on the wiring substrate 10 makes it easier to retain the concave shape. Furthermore, bending stress is relaxed, making it possible to reduce occurrence of distortion. This makes it possible to suppress functional degradation of the device section 11A due to the distortion. Thus, it is possible to suppress degradation in image quality of an obtained image.

Moreover, in this embodiment, the photoelectric converter and the switching device (such as the address switch SW1 and the switch SW2 described above) are formed not on the wiring substrate 10 but in the device section 11A. In other words, in this embodiment, the switching device is not formed in the wiring substrate 10 but disposed on the wiring substrate 10 in a state of being segmented with the photoelectric converter. Thus, the switching device is also less affected by bending and its degradation is suppressed. This leads to suppression of functional degradation of the device section 11A and improves reliability of the imaging apparatus 1.

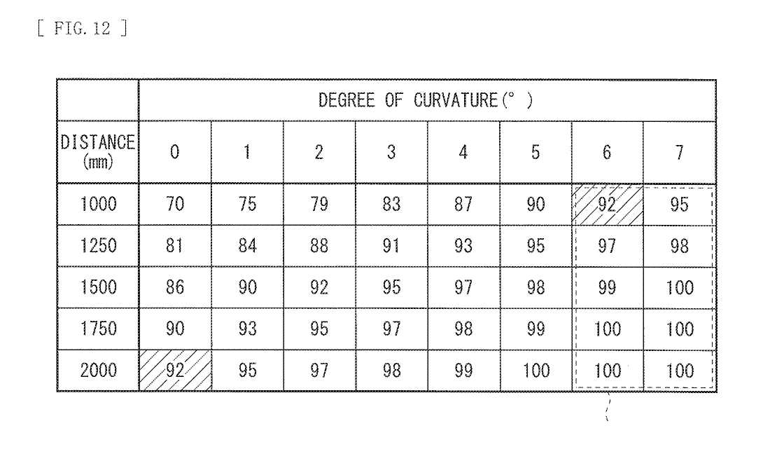

Furthermore, the degree of curvature of the concave shape of the pixel array section 11 being 6 degrees or more makes it possible to achieve sufficient image quality specifically for the large FPD application such as chest radiography. Now, FIG. 12 illustrates relations among the distance (mm) from the source 300, a degree of curvature) (°) of the imaging apparatus 1 (pixel array section 11), and sensitivity (%) in the periphery. It is to be noted that the size of the pixel array section is assumed to be 4300 mm×4300 mm. In the radiography, it is assumed that the light is regarded as being substantially parallel at a location 2000 mm away from the source and sufficient sensitivity is obtainable even in the periphery. Moreover, guidelines specify that the distance is 1000 mm in terms of ceiling height and operability upon shooting in the recumbent position.

For example, in a case where the degree of curvature is 0 degrees, that is, in a case where the pixel array section has a flat shape as in the comparative example 1, sensitivity in an outermost periphery is about 92% (92.3%) at a distance of 2000 mm from the source 300. This is ideal peripheral sensitivity. Now, in order to downsize the entire apparatus or to extend the source life by reducing the amount of radiation exposure, it is desirable to set the distance between the pixel array section and the source as short as possible. In a case where the distance is reduced to 1000 mm in the range specified by the guidelines, the light is not regarded as parallel light, and the peripheral sensitivity lowers to 70%, which results in too large sensitivity loss.

In such a case, increasing the degree of curvature, that is, allowing the pixel array section 11 to have a concave shape makes it possible to increase the peripheral sensitivity. Specifically in a case where the distance is close to 1000 mm as specified by the guidelines, the ideal value of the peripheral sensitivity (92% or higher) is achieved in a case where the degree of curvature is 6 degrees or more (a portion A1 in FIG. 12). For this reason, the degree of curvature of the concave shape of the pixel array section 11 is 6 degrees or more, which makes it possible to suppress reduction in peripheral sensitivity specifically for the large FPD application such as the chest radiography, thereby obtaining sufficient image quality.

As described above, in this embodiment, the plurality of device sections 11A including the photoelectric converters are disposed to collectively form the concave shape, which makes it possible to suppress sensitivity degradation in the periphery, as compared with a case of disposing the device sections 11A in a flat shape. Moreover, disposing the plurality of device sections 11A spaced from one another on the wiring substrate 10 makes it easier to retain the concave shape, and makes it possible to reduce occurrence of distortion due to bending stress, which allows for suppression of functional degradation of the device section 11A. This makes it possible to suppress degradation in image quality of the obtained image.

Modification examples of the above-described embodiment are described below. In the following, components similar to those in the above embodiment are denoted by same reference numerals, and description thereof is omitted as appropriate.

### MODIFICATION EXAMPLE 1

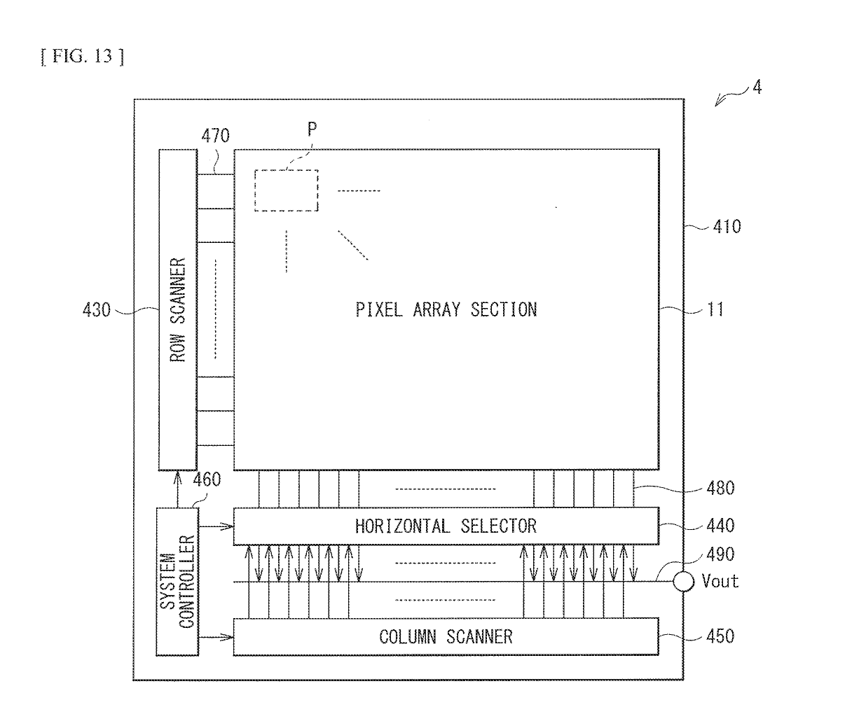

FIG. 13 illustrates a functional configuration of an imaging apparatus (imaging apparatus 4) according to a modification example 1. Although description of the above-described embodiment involves the configuration in which the pixel array section 11 includes the active pixel circuit, in this modification example, the pixel array section 11 includes a so-called passive pixel circuit. The imaging apparatus 4 includes, for example, the pixel array section 11 and a driver that drives the pixel array section 11 on a substrate 410. The driver includes, for example, a row scanner 430, a horizontal selector 440, a column scanner 450, and a system controller 460.

In the pixel array section 11, like the above-described embodiment, the plurality of device sections 11A are disposed in a matrix. Pixel drive lines 470 extending in a row direction and vertical signal lines 480 extending in a column direction are coupled to the device sections 11A. The vertical signal lines 480 each transmit a drive signal for signal readout from the device section 11A.

The row scanner 430 includes a shift register, an address decoder, and the like. The row scanner 430 is a pixel driver that drives the respective device sections 11A in the pixel array section 11 in units of rows, for example. A signal outputted from each of the device sections 11A in a pixel row selectively scanned by the row scanner 430 is supplied to the horizontal selector 440 via the respective vertical signal lines 480. The horizontal selector 440 includes, for example, an amplifier, a horizontal selection switch, and the like provided for each vertical signal line 480.

The column scanner 450 includes, for example, a shift register, an address decoder, and the like, and sequentially drives respective horizontal selection switches of the horizontal selector 440 while scanning those horizontal selection switches. Such selection and scanning performed by the column scanner 450 allows signals of respective unit pixels P transmitted via the respective vertical signal lines 480 to be sequentially outputted to a horizontal signal line 490. The thus-outputted signals are transmitted to the outside of the substrate 410 via the horizontal signal line 490.

A circuit portion including the row scanner 430, the horizontal selector 440, the column scanner 450, and the horizontal signal line 490 may be formed directly on the substrate 410 or may be provided in an external control IC. Alternatively, the circuit portion may be formed in any other substrate coupled by means of a cable or the like.

The system controller 460 receives a clock provided from the outside of the substrate 410, data on instructions of operation modes, and the like, and outputs data such as internal information of the imaging apparatus 4. Further, the system controller 460 includes a timing generator that generates various timing signals, and controls driving of peripheral circuits such as the row scanner 430, the horizontal selector 440, and the column scanner 450 on the basis of the various timing signals generated by the timing generator.

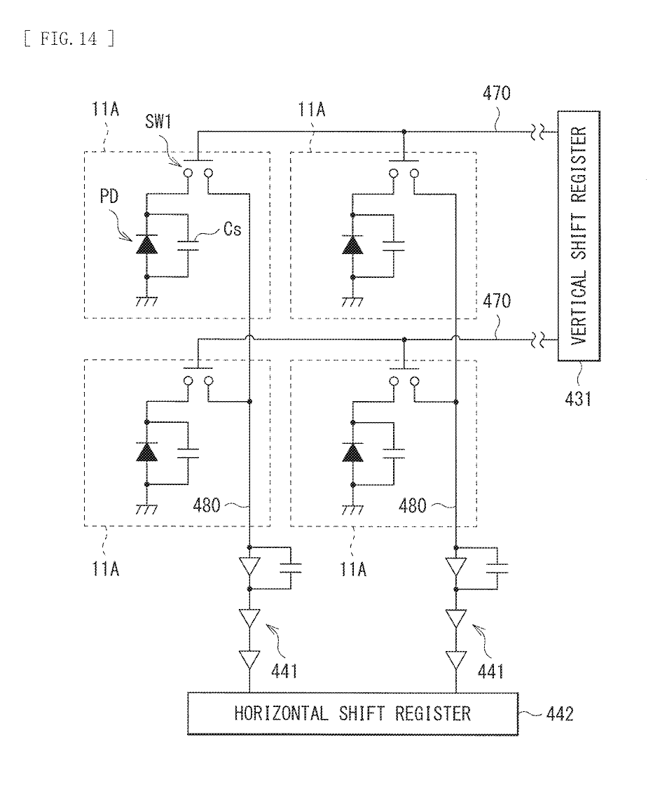

FIG. 14 illustrates a circuit configuration of the pixel array section 11 according to the modification example 1. In this modification example, the device section 11A includes, for example, the photodiode PD, the address switch SW1, and a capacitive component Cs. The address switch SW1 is coupled to the pixel drive line 470, and is subjected to on-off control by a vertical shift register 431 that configures a portion of the row scanner 430. It is to be noted that FIG. 14 also illustrates an amplifier 441 and a horizontal shift register 442 that configure a portion of the horizontal selector 440.

In this modification example, electric charge accumulated in the photodiode PD is sent to the vertical signal line 480 by the address switch SW1 being switched in each pixel. The electric charge is converted into voltage by the amplifier 441 and then read out to the outside.

### APPLICATION EXAMPLE

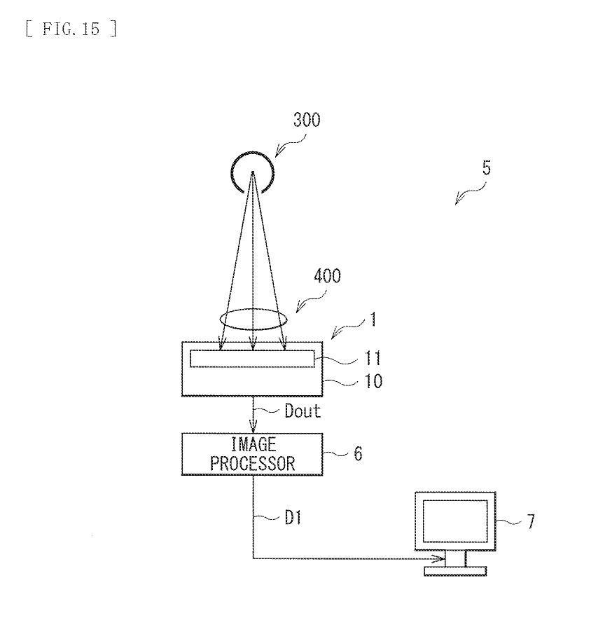

FIG. 15 illustrates an example of a functional configuration of an imaging display system (imaging display system 5) according to an application example. The imaging display system 5 includes, for example, the imaging apparatus 1 including the above-described pixel array section 11, an image processor 6, and a display apparatus 7. The image processor 6 performs predetermined image processing on an imaging signal Dout obtained by the imaging apparatus 1. The display apparatus 7 displays an image on the basis of the imaging signal Dout obtained by the imaging apparatus 4, and specifically displays an image based on the imaging signal processed by the image processor 6 (display signal D1).

In this embodiment, a component having passed through the object 400 of the radioactive ray emitted from the source 300 to an object 400 is detected by the imaging apparatus 1 to obtain the imaging signal Dout. The imaging signal Dout is inputted to the image processor 6 and is subjected to predetermined processing in the image processor 6. The signal subjected to the image processing is outputted to the display apparatus 7, and an image corresponding to the signal is displayed on a monitor screen of the display apparatus 7.

The imaging display system 5 using the imaging apparatus 1 is preferably used as an x-ray equipment and a CT (Computed Tomography) equipment that shoots, for example, chest, head, abdomen, knee, etc. In addition, the imaging display system 5 is also applied to dental panoramic radioscopy. Moreover, the imaging display system 5 is applicable not only to medical use but also to component inspection, baggage inspection, etc.

### MODIFICATION EXAMPLE 2

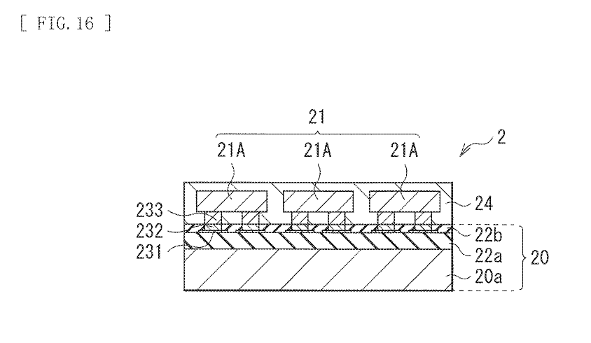

FIG. 16 illustrates a specific configuration example of a display apparatus (display apparatus 2) according to a modification example 2. Although description of the above-described embodiment involves the configuration example of the imaging apparatus in which the pixel array section has a concave shape, this configuration of the pixel array section is applicable not only to the imaging apparatus but also to the display apparatus.

The display apparatus 2 includes, for example, a pixel array section 21 including a plurality of display pixels (device sections 21A) disposed in two dimensions on a wiring substrate 20. The wiring substrate 20 includes a plurality of wiring layers (wiring layers 231) on a substrate 20a including, for example, glass, silicon (Si), an organic resin, or the like.

The plurality of device sections 21A each include a light emitting device such as a light emitting diode (LED) and are disposed to be spaced from one another (have a gap between the device sections 21A). Each of the plurality of device sections 21A is soldered on the wiring substrate 20 and electrically coupled to the wiring layer 231 of the wiring substrate 20. The wiring layer 231 is formed on an insulating film 22a and embedded in an insulating film 22b. A UBM 232 penetrating the insulating film 22b is formed on the wiring layer 231, and the device sections 21A are disposed on the UBM 232 with a solder layer 233 in between. A buried layer 24 is formed to fill the gap between the device sections 21A. The pixel array section 21 of the display apparatus 2 having such a configuration has a concave shape as described above as a whole.

In this modification example, the plurality of device sections 21A including the light emitting devices collectively form a concave shape and are disposed to be spaced from one another, which makes it easier to retain the concave shape, and makes it possible to reduce occurrence of distortion due to bending stress. This makes it possible to suppress functional degradation of the device section due to the distortion. Thus, it is possible to suppress degradation in image quality of a displayed image.

As described above, the present disclosure has been described above with reference to some embodiments and modification examples, but the present disclosure is not limited thereto, and may be modified in a variety of ways. It is to be noted that the effects described herein are merely examples, and may be other effects, and may further include other effects.

Moreover, for example, the present disclosure may have the following configurations.
(1)

An imaging apparatus, including:

a substrate; and

a plurality of device sections each including a photoelectric converter and disposed on the substrate to be spaced from one another and to collectively form a concave shape.
(2)

The imaging apparatus according to (1), in which the substrate includes glass, silicon (Si), or an organic resin.
(3)

The imaging apparatus according to (1) or (2), in which each of the plurality of device sections includes the photoelectric converter and one or more switching devices for driving of the photoelectric converter.
(4)

The imaging apparatus according to any one of (1) to (3), in which a degree of curvature of the concave shape is 6 degrees or more.
(5)

The imaging apparatus according to any one of (1) to (4), in which the concave shape is gently curved from a center toward a periphery of the plurality of device sections.
(6)

The imaging apparatus according to any one of (1) to (5), in which the concave shape has a curvature.
(7)

The imaging apparatus according to any one of (1) to (6), in which the substrate has a curved shape that includes a concave face on a side on which the device sections are located.
(8)

The imaging apparatus according to (7), in which respective concave shapes of the plurality of device sections are formed more gently than the curved shape of the substrate.
(9)

The imaging apparatus according to any one of (1) to (8), further including a wavelength conversion layer that is formed on the plurality of device sections and converts an incident radioactive ray into light.
(10)

The imaging apparatus according to (9), in which the wavelength conversion layer includes a scintillator having a granular shape.
(11)

The imaging apparatus according to (9), in which the wavelength conversion layer includes a scintillator having a columnar shape.
(12)

The imaging apparatus according to any one of (1) to (11), in which the wavelength conversion layer has a concave shape corresponding to the concave shape of the plurality of device sections.
(13)

The imaging apparatus according to any one of (1) to (12), further including a buried layer formed in a gap between the plurality of device sections.
(14)

The imaging apparatus according to any one of (1) to (13), in which

the substrate includes a plurality of wiring layers, and

each of the plurality of device sections is electrically coupled to the wiring layer via solder.
(15)

An imaging display system provided with an imaging apparatus, the imaging apparatus including:

a substrate; and

a plurality of device sections each including a photoelectric converter and disposed on the substrate to be spaced from one another and to collectively form a concave shape.
(16)

A display apparatus including:

a substrate: and

a plurality of device sections each including a light emitting device and disposed on the substrate to be spaced from one another and to collectively form a concave shape.

This application is based upon and claims the benefit of priority of the Japanese Patent Application No. 2016-31110 filed with the Japan Patent Office on Feb. 22, 2016, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. An imaging apparatus, comprising:
a substrate; and
a plurality of device sections each including a photoelectric converter and disposed on the substrate to be spaced from one another and to collectively form a concave shape.

2. The imaging apparatus according to claim 1, wherein the substrate includes glass, silicon (Si), or an organic resin.

3. The imaging apparatus according to claim 1, wherein each of the plurality of device sections includes the photoelectric converter and one or more switching devices for driving of the photoelectric converter.

4. The imaging apparatus according to claim 1, wherein a degree of curvature of the concave shape is 6 degrees or more.

5. The imaging apparatus according to claim 1, wherein the concave shape is gently curved from a center toward a periphery of the plurality of device sections.

6. The imaging apparatus according to claim 1, wherein the concave shape has a curvature.

7. The imaging apparatus according to claim 1, wherein the substrate has a curved shape that includes a concave face on a side on which the device sections are located.

8. The imaging apparatus according to claim 7, wherein respective concave shapes of the plurality of device sections are formed more gently than the curved shape of the substrate.

9. The imaging apparatus according to claim 1, further comprising a wavelength conversion layer that is formed on the plurality of device sections and converts an incident radioactive ray into light.

10. An imaging apparatus according to claim 9, wherein the wavelength conversion layer includes a scintillator having a granular shape.

11. The imaging apparatus according to claim 9, wherein the wavelength conversion layer includes a scintillator having a columnar shape.

12. The imaging apparatus according to claim 9, wherein the wavelength conversion layer has a concave shape corresponding to the concave shape of the plurality of device sections.

13. The imaging apparatus according to claim 1, further comprising a buried layer formed in a gap between the plurality of device sections.

14. The imaging apparatus according to claim 1, wherein
the substrate includes a plurality of wiring layers, and
each of the plurality of device sections is electrically coupled to the wiring layer via solder.

15. An imaging display system provided with an imaging apparatus, the imaging apparatus comprising:
a substrate; and
a plurality of device sections each including a photoelectric converter and disposed on the substrate to be spaced from one another and to collectively form a concave shape.

16. A display apparatus comprising:
a substrate; and
a plurality of device sections each including a light emitting device and disposed on the substrate to be spaced from one another and to collectively form a concave shape.
